(19) United States
(12) Patent Application Publication
(10) Pub. No.: US 2026/0311921 A1
(43) Pub. Date: Oct. 8, 2026

(54) PWM ELECTROMECHANICAL VALVE DRIVER WITH DUAL PATH CURRENT RECIRCULATION

(71) Applicant: Siemens Healthcare Diagnostics Inc., Tarrytown, NY (US)

(72) Inventor: Charles V. Cammarata, Ledgewood, NJ (US)

(73) Assignee: Siemens Healthcare Diagnostics Inc., Tarrytown, NY (US)

(21) Appl. No.: 19/485,411

(22) PCT Filed: May 17, 2024
(86) PCT No.: PCT/US2024/029894

§ 371 Date: Nov. 18, 2025

Related U.S. Application Data
(60) Provisional application No. 63/504,188, filed on May 24, 2023.

(51) Int. Cl. H01F 7/06; H03K 7/08; H03K 17/081

(52) U.S. Cl. CPC H01F 7/064; H03K 7/08; H03K 17/08104; H03K 17/08112; H03K 2217/0063; H03K 2217/0072

(57) ABSTRACT

Driver circuits for inductive loads, such as electromechanical valves and actuators are provided that utilize two transistors and an arrangement of diodes to provide a slow-decaying recirculation path during pulse-width modulation operation and a fast-decaying path when transitioning to an OFF or de-actuation transition.

### CROSS REFERENCE TO RELATED APPLICATIONS

This application claims the benefit of U.S. Provisional Patent Application No. 63/504,188, entitled “PWM ELECTROMECHANICAL VALVE DRIVER WITH DUAL PATH CURRENT RECIRCULATION” filed May 24, 2023, the disclosure of which is hereby incorporated by reference in its entirety for all purposes.

### TECHNICAL FIELD

The invention relates to driving electromechanical coils or other inductive loads and, more particularly, to drive circuits for driving electromechanical actuators or valves with high precision and control.

### BACKGROUND

Electromechanical valves (EVs) for either liquid or gas are an important part of industrial process control systems, including laboratory automation or diagnostic systems. EVs commonly utilize electromechanical actuators that include an inductive load, such as an actuator coil. EVs are driven by an electronic circuit that controls electrical power to an inductive coil which actuates the EV. The power source is removed to de-actuate the EV.

There are two challenges that arise with EVs in systems where precision is demanded, such as in medical devices and diagnostic analyzers. First, EVs typically have a limit to the amount of time they can be energized at their full DC current rating, due to the effects of heating via power dissipation. Excessive heating negatively impacts long term reliability of EVs. Thus, keeping EVs actuated at full current for too long too often can greatly reduce the mean-time-to-failure of EVs. Second, de-actuation time of the EV can be critical in medical device analyzers as it impacts precision of fluid aspirate and dispense. De-actuation time of the EV is proportional to the rate at which its coil current decays to zero (or at least to a level below which the valve closes), after the power source is removed.

The prior art commonly addresses the first challenge (excessive continuous operation current) by using pulse width modulation (PWM) technique. PWM can be implemented with common commodity components such as transistors (such as one or more MOSFET or BJT), which are operated by a microcontroller, or by integrated circuits specialized for this purpose. This allows the valve or solenoid to be held in an activated state without driving the coil at continuous high current. This is commonly referred to as a “holding current”. The second challenge (reduced de-activation times) can be addressed by implementing a voltage suppressor, such as by using a diode with well-defined reverse bias breakdown characteristics. For example, transient voltage suppressor (TVS) or Zener diodes can provide in an inductive recirculation path (in contrast to a traditional rectifier diode topology.) However, use of this approach is not favorable for PWM operation as it results in increased energy loss during PWM operation. Thus, prior art techniques typically address one of these challenges, but not both.

One can achieve both reduced applied EV power for continuous operation and improved de-actuation times by using a bi-polar drive, such as a four quadrant “H” bridge. This can provide PWM operation when actuating the EV and fast decay for de-actuation by reversing the voltage polarity on the inductive drive coil. Alternatively, to achieve both reduced applied EV power for continuous operation and improved de-actuation times can be achieved by implementing two separate voltage levels, a voltage steering circuit, TVS or Zener diode in the recirculation path. An actuation level voltage/current level is applied to the inductor for actuating the EV followed by a reduced holding voltage/current to maintain the actuated state of the EV. This requires a steering circuit which can be controlled as a function of time. The TVS or Zener diode in the recirculation path increases the rate of current decay while de-actuating by operating in a reverse bias mode. Each of these options requires additional components and added cost.

### SUMMARY

Described herein are systems and methods for driving inductive loads, such as electromechanical valves and actuators, which enables 1) programmatic pulse-width modulation power control when the load is energized and 2) programmatic pulse-width modulation of current decay control of the inductive load at turn-off, both using low-cost simple components.

In one embodiment, the present disclosure is directed to driver circuit (50) configured to drive an inductive load (L2), which includes first and second transistors (T4, T3) configured to be operated in series with the inductive load between a voltage source and ground, wherein a first control signal (10) to the first transistor (T4) determines an actuated state of the inductive load and a second control signal (20) to the second transistor (T3) operates the second transistor in a pulse-width modulated state during the actuated state. A first rectifier diode (R6) is electrically coupled in parallel to the first transistor and the inductive load, and a second rectifier diode (R7) is electrically coupled in parallel to the second transistor and the inductive load. Current flows along a path defined by the first rectifier diode (R6), the first transistor (T4) and the inductive load when the second transistor (T3) in an off phase of the pulse-width modulated state and current flows along a path defined by the first rectifier diode (R6), the second rectifier diode (R7), and the inductive load (L2) when the first transistor transitions from an on state to an off state.

In some embodiments, the driver circuit includes a Zener diode (Z10) in series with the second rectifier diode such that current also flows through the Zener diode (Z10) when the first transistor transitions from an on state to an off state. In some embodiments, the driver circuit includes a transient voltage suppression (TVS) diode (Z10) in series with the second rectifier diode such that current also flows through the TVS diode (Z10) when the first transistor transitions from an on state to an off state. In some embodiments, the first transistor is a high-side transistor and the second transistor is a low-side transistor. In some embodiments, the first transistor is a low-side transistor and the second transistor is a high-side transistor. In some embodiments, the first and second transistors are MOSFETs. In some embodiments, the first and second transistors are BJTs.

In another embodiment, a driver circuit (52) is configured to drive an inductive load (L2), and includes first and second transistors (T6, T5) configured to be operated in series with the inductive load between a voltage source and ground, wherein a first control signal (12) to the first transistor (T6) determines an actuated state of the inductive load and a second control signal (22) to the second transistor (T5) operates the second transistor in a pulse-width modulated state during the actuated state. A controlled reverse breakdown diode (Z8) is electrically coupled in parallel to the first transistor and the inductive load, and a rectifier diode (R8) is electrically coupled in parallel to the second transistor and the inductive load. Current flows along a path defined by the controlled reverse breakdown diode (Z8), the first transistor (T6), and the inductive load when the second transistor (T5) is in an off phase of the pulse-width modulated state and current flows along a path defined by the controlled reverse breakdown diode (Z8), the rectifier diode (R8), and the inductive load (L2) when the first transistor transitions from an on state to an off state.

In some embodiments, the controlled reverse breakdown diode (Z8) is a Zener diode. In some embodiments, the controlled reverse breakdown diode (Z8) is a transient voltage suppression (TVS) diode. In some embodiments, the first transistor is a high-side transistor and the second transistor is a low-side transistor. In some embodiments, the first transistor is a low-side transistor and the second transistor is a high-side transistor. In some embodiments, the first and second transistors are MOSFETs. In some embodiments, the first and second transistors are BJTs.

### FIGURES

The accompanying drawings, which are incorporated in and form a part of the specification, illustrate the embodiments of the invention and together with the written description serve to explain the principles, characteristics, and features of the invention. In the drawings:

FIG. 1 is circuit diagram of a prior art driver circuit;

FIG. 2 is circuit diagram of a prior art driver circuit;

FIG. 3 is circuit diagram of a prior art driver circuit;

FIG. 4 is circuit diagram of a prior art driver circuit;

FIG. 5 is circuit diagram of a prior art driver circuit;

FIG. 6 is circuit diagram of a prior art driver circuit;

FIG. 7 is circuit diagram of a driver circuit for use with some embodiments;

FIG. 8 is circuit diagram of a driver circuit for use with some embodiments;

FIG. 9 is circuit diagram of a driver circuit for use with some embodiments;

FIG. 10 is circuit diagram of a driver circuit for use with some embodiments; and

FIG. 11 is circuit diagram of a driver circuit for use with some embodiments.

### DESCRIPTION

This disclosure is not limited to the particular systems, devices and methods described, as these may vary. The terminology used in the description is for the purpose of describing the particular versions or embodiments only and is not intended to limit the scope.

Embodiments disclosed herein create a novel circuit topology that can reduce delivered power to an EV, allow it to operate continuously, and reduce the de-actuation time of the EV to improve its functional response of the EV.

Prior art unipolar (high or low side) EV drive circuits are generally either optimized for PWM operation or optimized for ON/OFF with fast de-actuation (decay) operation, but not both. Additionally, previous bipolar EV drive circuits can offer optimized performance for PWM operation and fast de-actuation (decay) operation but are more complex in design and control, as compared to unipolar EV drive circuits.

Embodiments disclosed herein create a selectable dual recirculation path topology which permits the use of low cost commercially available transistors, diodes and/or transient voltage suppressors. Embodiments create a PWM capable EV driver with a selectable dual path current recirculation. One recirculation path has “slow decay” characteristics, and the other path has “fast decay” characteristics. The recirculation path can be PWM controlled to vary the amount of slow vs fast decay over unit time, and hence vary the overall decay rate.

In some embodiments, only two logic type signals are required for operation: one signal for energizing and decay path select signal. These can be implemented with many of today's microcontrollers as well as with hardware only monostable circuits (one-shot). This approach offers the pertinent advantages of bipolar drive, namely efficient PWM operation and optimized de-actuation operation, while offering a circuit that can be achieved using fewer parts (which are low-cost commodity components with multiple suppliers) and a simpler control scheme with less I/O burden in comparison to other known designs. Furthermore, both the energizing signal and decay path signal can be PWM controlled, allowing additional tuning abilities.

Embodiments are explained with respect to an EV, which is illustrated as an inductive load. However, it should be understood that these embodiments work equally well with other inductive loads (such as other solenoid actuation or other electromechanical devices) that use PWM control and desire fast de-actuation times.

For non-latching EVs, unipolar drives are typically implemented due to their simplicity. Assuming an EV coil is at a de-energized (zero current) state, a nominal excitation voltage (typically 24V) is applied using a switching device such as a transistor. De-actuation is typically achieved by “opening the switch,” thereby removing the voltage source from the EV's inductor. The switch can either control the +V connection to the coil, or the −V (GND) connection to the coil. Due to inductive physics, the inductor current cannot instantaneously change.

Therefore, current will continue to flow when the switch is open, and the inductor begins to source current and will continue to do so as the magnetic field in and around the inductor collapses. This current needs to have a path to recirculate. Otherwise, the inductor will induce a high voltage that will arc and damage other components. Typical drive circuits use a rectifying diode connected in parallel with the inductor (often referred to as a flyback or freewheeling diode), such that it is reverse biased when an energizing power source is applied. This diode provides a current recirculation path for the inductor when the power source is removed. Eventually, due to circuit losses, this current will decay to zero.

The time it takes to decay the current to reach zero (or a threshold value) impacts the de-actuation time of the EV. As mentioned previously, this decay rate is inversely proportional to the voltage across the inductor during the recirculation period. Use of traditional rectifier diodes for recirculation will typically apply −0.5V across the coil, with respect to the energized voltage polarity. Therefore, the de-actuation time will exceed the actuation time due to the slower current decay associated with a smaller applied coil voltage during recirculation. Use of a diode is common practice due to its low cost, reliability, wide availability and commodity nature.

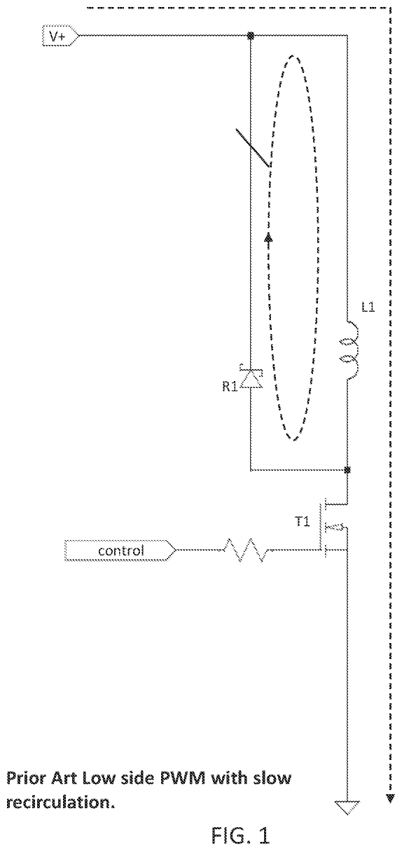

Common examples of high and low side driving circuits for unipolar non-latching EVs are provided in FIGS. 1-6. In these figures, the solid path illustrates the current path while the switch is closed (energizing), and the dotted path illustrates the current path while the switch is open, causing current to recirculate (de-energize). When the transistor is active, based on a control signal at the appropriate level, it allows current from V+ to flow in the inductive load, and the EV valve quickly actuates. When the transistor is turned off by the control signal, the current no longer can flow through the transistor, but it continues to flow due to the inductive load. Diodes allow the current to still flow along a recirculating path as the current decays to allow the EV to de-actuate.

In these figures, the inductor represents the EV. Exemplary transistors in these examples use P channel MOSFET for high side drive and N channel MOSFET for low side drive, however either N, P, NPN, PNP transistors can be used in either the high or low side locations, with appropriate gate/base drivers.

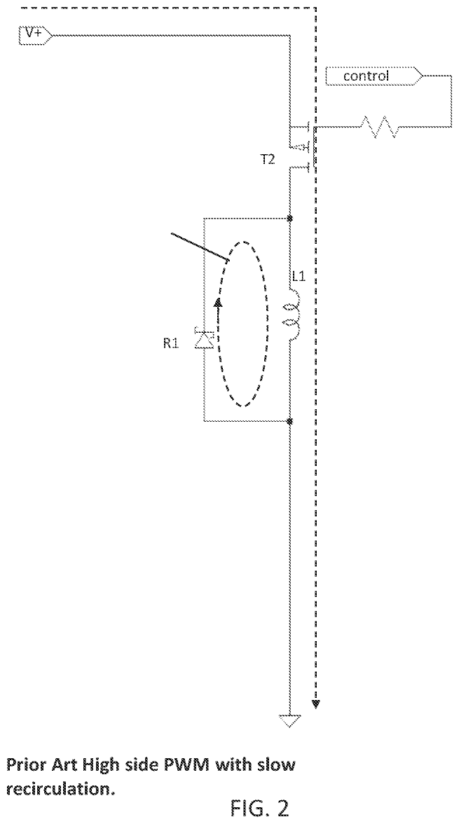

FIGS. 1 and 2 show a driver circuit that provides a recirculation path at shutoff using a rectifying diode R1 in parallel with an inductive load L1. When the control signal turns on the transistor (T1 or T2, depicted as NMOS and PMOS), current flows in the load L1 for V+ to ground. The rectifying diode R1 is reverse biased in parallel to the inductive load, so no current flows through the diode. When the transistor is switched off, no current flows from V+ to ground, which creates a voltage swing in the inductive load L1. This forward biases the rectifying diode R1, creating the dotted recirculation path. The voltage drop across the diode is only equal to the forward bias threshold voltages (typically around 0.5V).

PWM control of non-latching EVs is often used to reduce the applied power to the EV coil, after initial actuation, and enables continuous actuation. The same circuit as described above can be used. The switching device is repetitively turned on for a period and off for a period, resulting in a cyclic current increase and current decay (decrease) in the coil. Typically, these on and off times result in PWM signals in the 20 kilohertz range, which is above the human audible range. Minimizing the current decay, or “slow decay”, during PWM off periods minimizes losses and results in more efficient power delivery. Therefore, a lower applied recirculation voltage across the inductor during the OFF period is desirable. Use of traditional rectifier diodes for recirculation are well suited for this since they are offered with voltage drops <0.5V, are simple to use, highly reliable, and low cost. Synchronous rectification circuits use a MOSFET in place of the diode. This can offer increased efficiency over a diode, at the expense of design complexity.

FIGS. 1-2 employ a slow-decay topology. The slow decay, while beneficial for PWM operation, imposes a longer de-actuation time characteristic when the valve/inductive load is turned off. Accordingly, the examples in FIGS. 1 and 2 have good performance in the PWM phase but have undesirably slow recirculation decay during de-actuation. Comparing a 0.5V diode drop to a typical 24-volt actuation voltage level, we can see that the de-actuation time will be longer than actuation time when using standard rectifier diodes.

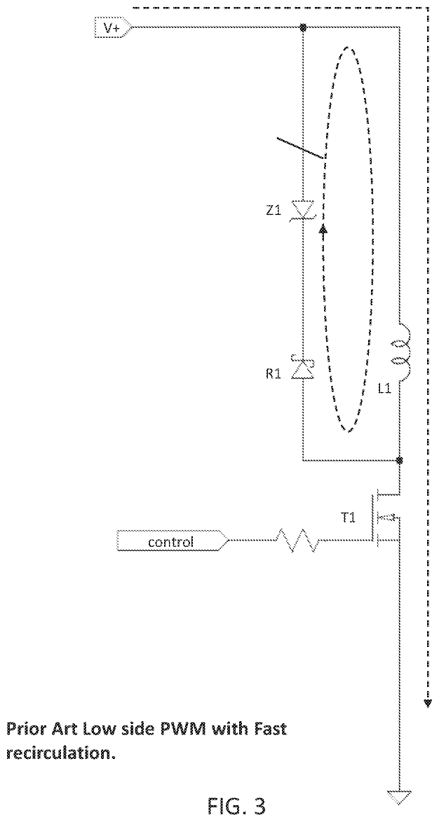

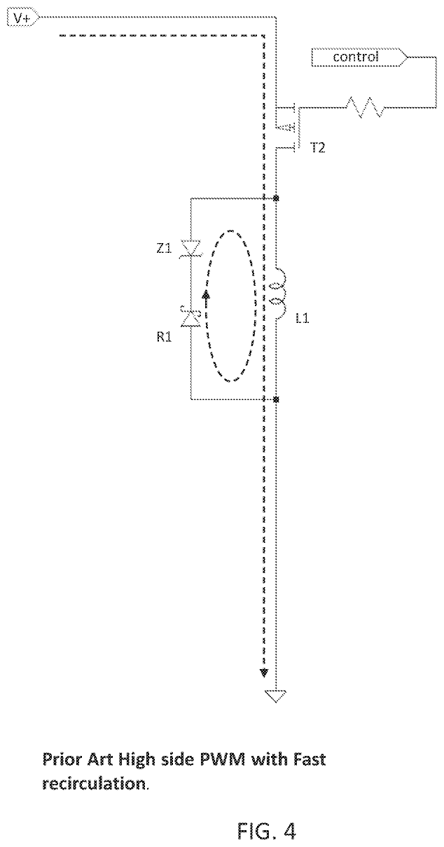

Alternatively, for non-latching EVs, prior art sometimes implements fast decay recirculation circuits FIGS. 3-4 that use both a rectifier diode R1 and Zener diode Z1 in series and in parallel with the load L1. The diodes are configured such that the recirculation current forward biases the rectifier diode R1 and reverse biases the Zener diode Z1. This allows current to flow around the recirculating path when the voltage across the load exceeds the reverse bias breakdown of diode Z1 and the forward bias threshold of diode R1. This results in a voltage drop equal to the rectifier diode forward voltage drop and Zener diode reverse voltage (Zener voltage) drop. This makes it possible to apply higher voltages across the inductor L1 during the recirculation phase, which increases the decay rate. This has the benefit of increasing the de-actuation response time of the EV, but it is sub-optimal for PWM applications as it greatly reduces PWM efficiency.

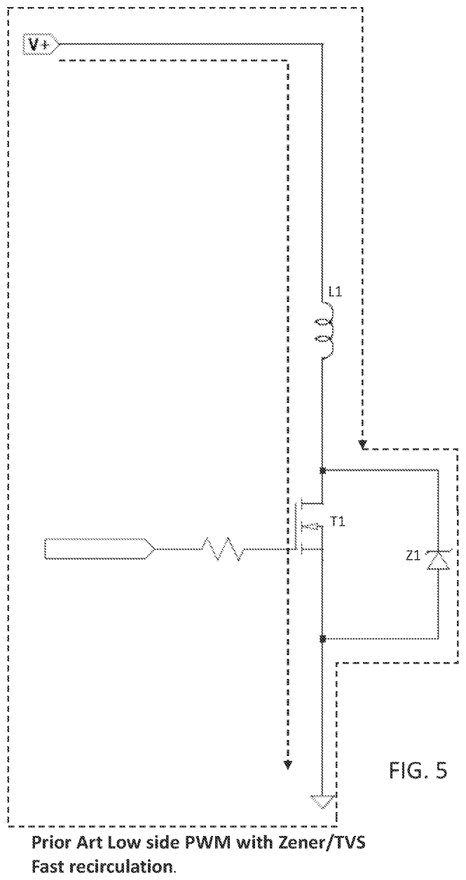

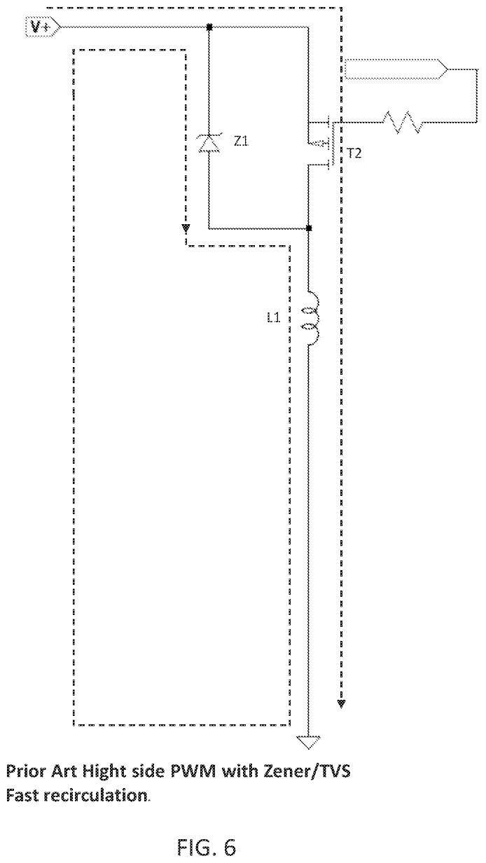

The driver circuits in FIGS. 5 and 6 use a different approach, instead placing Zener diode Z1 in parallel with the transistor and series with the inductive load L1. Thus, when the transistor is turned off, the current has a path when the voltage across load L1 reverse biases diode Z1 beyond the breakdown voltage, quickly decaying the current.

Note that in all examples and embodiments a transient voltage suppressor (TVS diode) can also be used in place of the Zener diode unless otherwise specified. Zener diodes are designed specifically to conduct in a reverse bias mode when biased beyond the Zener voltage for the diode. TVS diodes operate slightly differently but are also designed to conduct in a reverse bias mode when a threshold voltage exceeds an avalanche breakdown threshold. Both of these types of diodes are designed to have a well-defined and usable reverse bias breakdown characteristics without damaging the diode. For purposes of this description, diodes such as Zener and TVS diodes that are designed for well-defined, safe conduction above a reverse bias threshold will be referred to as “controlled reverse breakdown” diodes. This should be contrasted to rectifier/Schottky diodes, which are not designed to conduct in a reverse bias mode (and if an avalanche breakdown does occur, it can be unintentional and can damage the diode. The specific controlled reverse breakdown selected for the embodiments disclosed herein will be at the discretion of the designer, selecting a reverse-bias breakdown voltage to create the desired fast-decay de-actuation transient and cost characteristics for the specific application. Embodiments are generally disclosed that will work with either Zener or TVS controlled reverse breakdown diodes. This type of circuitry also can typically be implemented with low cost, widely available commodity components, with multiple suppliers.

In the exemplary schematics below, the inductor represents the EV. High side embodiments using P channel MOSFETs are shown, however the same high side topologies can be implemented with N channel MOSFETs, or BJT transistors, provided that the proper bias is implemented. Additionally. The same recirculation topologies can be used with low side drive as well.

In comparison, latching EVs require current to be driven in one direction to actuate and driven in the opposite direction for de-actuation. A bi-polar drive is therefore required. Four quadrant “H” bridges are typically employed to achieve bi-polar operation with PWM capability. Many integrated circuit manufacturers offer a wide variety of single-chip PWM type bipolar drive control solutions for single phase motors such as coils, solenoids, valves, and brushed DC motors. With bi-polar drives, actuation and de-actuation times are inversely proportional to the applied voltage across the coil, for each bipolar state.

For non-latching EVs, a bipolar drive scheme, as used in the latching EV types, can be employed to create a “fast decay” mode, which is achieved by connecting the coil in the opposite polarity until the current reaches zero. In this implementation, the de-actuation response times can be reduced as compared to the rectifier diode recirculation approach. As stated earlier, many integrated circuit manufacturers offer single chip “H” bridge drive and control solutions for valves and other single phase motor windings which employ such features as slow, mixed, and fast decay modes, along with PWM control. These circuits can offer high performance and flexibility but are more complex in terms of circuitry and are more complex to control. Many “H” bridge integrated circuits are commercially available for control of both brushed DC motors and solenoids. Most integrated circuits of this variety are unique single-source type components, which are not desirable from a supply chain perspective.

For precision EV applications, particularly in medical diagnostic analyzers, actuation and de-actuation response times are critical, therefore drive circuitry that enables fast actuation and de-actuation response times are highly desirable. It is further desirable to create these circuits with low-cost, easily sourced components, such as diodes. Previous embodiments for unipolar high or low side EV drive circuits are either optimized for PWM operation or optimized for ON/OFF with fast de-actuation (decay) operation, but not both. Additionally, previous embodiments for bipolar EV drive circuits can offer optimized performance for PWM operation and fast de-actuation (decay) operation but are more complex in design and control, as compared to unipolar high or low side EV drive circuits.

Embodiments attempt to improve upon the unipolar problems with the prior art by using a dual recirculation path (two transistors) approach, allowing the driver to operate one way in a PWM mode and another way that creates fast current decay in the inductive load when the EV is switched off. Embodiments create a selectable dual recirculation path topology which permits the use of low-cost, commercially available transistors, diodes and/or TVS diodes. This creates a PWM capable EV driver with a selectable dual path current recirculation, where one recirculation path has “slow decay” characteristics (for use during a PWM ON state) and the other path has “fast decay” characteristics and provides recirculation during de-actuation phase. The recirculation path can be PWM controlled to vary the amount of slow vs fast decay over unit time, and hence vary the overall decay rate.

Only two logic type signals are required for operation in these dual path embodiments: one signal for energizing the EV by supplying current through the coil, and one decay path select signal to activate a fast-decay path. These signals can be implemented in any suitable manner, such as using a microcontroller or with hardware-only monostable circuits (one-shot). This approach offers the pertinent advantages of the bipolar drive, namely efficient PWM operation and optimized de-actuation operation, while offering a much simpler circuit that can be achieved using fewer components using a simpler control scheme with less IO burden, while using low-cost, widely available commodity components with multiple suppliers. Both the energizing signal and decay path signal can be PWM controlled. In exemplary embodiments, these signals will be described as an ON/OFF signal, which reflects the desired actuation state of the driver EV and determines whether the fast-decay path is available, and a PWM energizing signal that is modulated during the ON state to supply a modulated current through the coil. For example, the PWM energizing signal can be modulated above 20 KHz to reduce ripple and avoid the audio range.

Examples of exemplary novel low side PWM with dual recirculation paths are given below. In all schematics, a solid path represents actuation (energizing) state (not always shown when self-evident), the single-dotted path represents slow-decay for PWM operation (during the ON Phase), and the double-dotted path represents the fast-decay path for the de-actuation state (during the de-energizing phase transitioning to OFF).

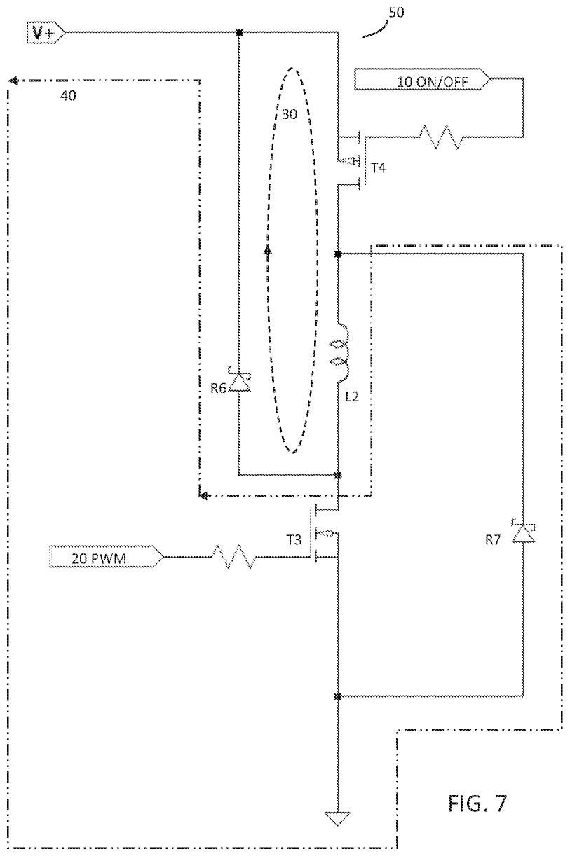

FIG. 7 is a schematic of an embodiment of a driver topology 50 that provides low side PWM with dual recirculation paths, including a regenerative path during de-actuation decay. High-side transistor T4 is controlled by the signal at ON/OFF pin 10. It provides a series path between V+ ground along with inductive load L2 and low-side transistor T3. Transistor T3 is controlled by the signal at PWM pin 20. Each of the ON/OFF and PWM pins described with respect to the embodiments in FIGS. 7-11 can be a pin of a control circuit such as a microcontroller or a dedicated microcontroller-controlled circuit. The control circuit creates an ON/OFF signal that is ON when current is required through the inductive load L2 (e.g., during actuation and holding in the actuated state). It is OFF at least during the transition from the actuated state to the de-actuated state and may remain off during the de-actuated state in some embodiments. The PWM signal operates in a PWM mode during the ON phase, allowing lower mean power to be supplied to the inductive load once actuation has occurred. The PWM signal is generally quiescent during the de-actuation phase of control. Not that the PWM may be modulated secondarily modulated and the ON/OFF signal can itself be modulated to create different control profiles tailored to the control needs.

Rectifying diode R7 is placed in parallel with transistor T3 and load L2, while rectifying diode R6 is placed in parallel with transistor T4 and load L2, such that a series path is created between V+ and ground via diodes R6 and R7 and load L2. Diodes R6 and R7 are forward biased when current flows from ground to V+, which provides a regeneration mode.

Current in coil L2 is energized when transistors T3 and T4 are ON, applying V+ voltage level to L2. Both R6 and R7 are reverse biased in this condition and block current flow. For PWM operation, T3 is PWM (ON/OFF) modulated at the desired frequency and duty cycle while T4 remains ON. When T3 is OFF and T4 is ON, R7 remains reverse biased and the current in L2 forward biases R6, producing a voltage across L2 equal in magnitude to the voltage drop across R6 and T4. The voltage drop across T4 is minimal since it is ON. This is the slow-decay state, which minimizes current ripple during PWM, illustrated by current path 30. When both transistors are OFF to de-actuate coil L2, the current in L2 forward biases diodes R6 and R7, producing a voltage across L2 equal in magnitude to V+ voltage, less the voltage drops of R6 and R7. Current re-generates back into the V+ rail. This is the fast-decay state that allows rapid de-actuation, shown by current path 40. Either transistor T3 and T4 can be PWM controlled when the other transistor is off to create a variable decay rate, modulating between paths 30 and 40.

In some embodiments, control of circuit 50 can be flipped, allowing transistor T4 to be operated under PWM control, while transistor T3 is operated under ON/OFF control. In this case, the current path defined by R7, T3 and L2 takes the place of the slow-decay state, like path 30.

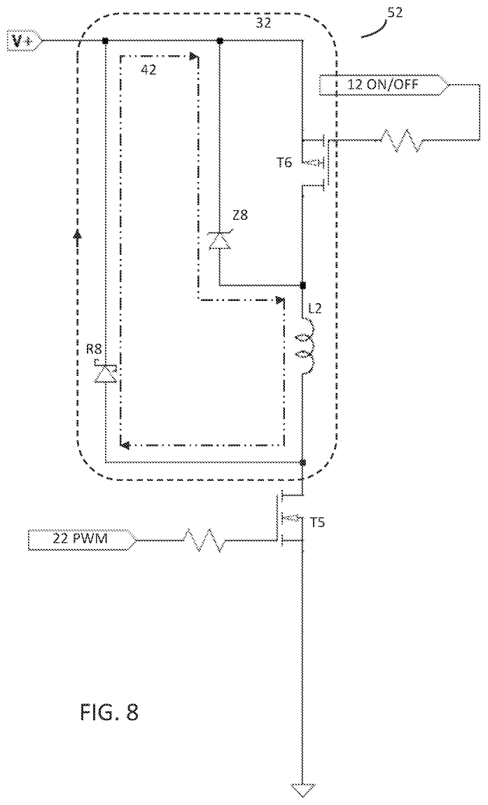

FIG. 8 is a schematic of an embodiment of a driver topology 52 that provides low side PWM with dual recirculation paths that utilizes a Zener or TVS diodes. High-side transistor T6 is controlled by the signal at ON/OFF pin 12. It provides a series path between V+ and ground along with inductive load L2 and low-side transistor T5. Transistor T5 is controlled by the signal at PWM pin 22. Rectifying diode R8 is placed in parallel with transistor T6 and load L2, while rectifying Zener/TVS diode Z8 is placed in parallel with transistor T6.

Current in coil L2 is energized when transistors T5 and T6 are ON, applying V+ voltage level to L2. Both diodes R8 and Z8 are reverse biased in this condition and block current flow. Note that both rectifier R8 and TVS (or Zener) Z8 should have a reverse standoff voltage rating of >V+. The breakdown voltage of Z8 will influence turn-off decay and can be selected accordingly.

For PWM operation, transistor T5 is PWM (ON/OFF) modulated at the desired frequency and duty cycle while T6 remains ON. When T5 is OFF and T6 is ON, current in L2 forward biases rectifier R8, producing a voltage across L2 equal in magnitude to the voltage drop across R8 and T6. The voltage drop across transistor T6 is minimal since it is ON and allows bypass of Zener/TVS diode Z8. This is the slow-decay state, illustrated by current path 32. When both transistors T5 and T6 are OFF, current in coil L2 forward biases rectifier R8 and produces a voltage sufficient to break down Zener/TVS diode Z8, causing a voltage across L2 equal to voltage drops of R8 and Z8. This is the fast-decay state, illustrated by current path 42. Transistor T6 can be PWM controlled while T5 is off to create a variable decay rate, modulating between paths 32 and 42.

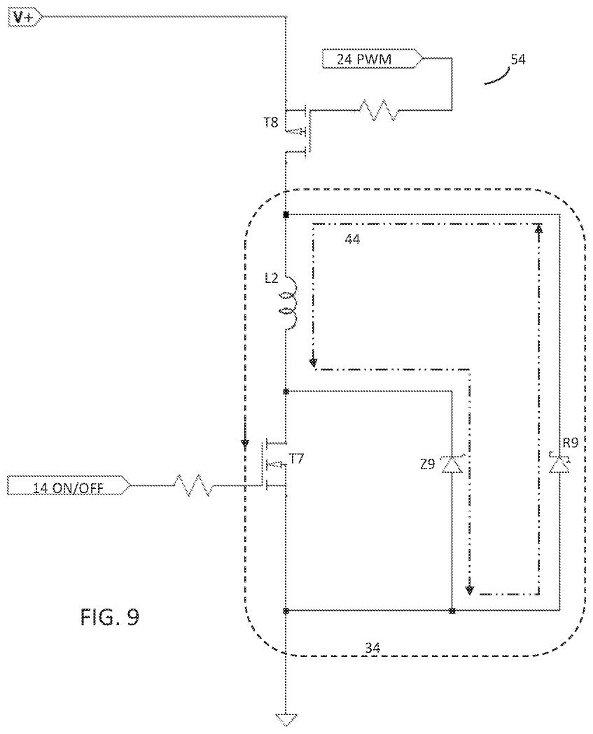

FIG. 9 is a schematic of an embodiment of a driver topology 54 that provides high-side PWM with dual recirculation paths that utilizes a Zener or TVS diodes. This operates similarly to circuit 52 with the low-side and high-side swapped. High-side transistor T8 is controlled by the signal at PWM pin 24; low-side transistor T7 is controlled by the signal at ON/OFF pin 14. It provides a series path between V+ and ground along with inductive load L2 and transistors T7 and T8. Rectifying diode R9 is placed in parallel with transistor T7 and load L2, while rectifying Zener/TVS diode Z9 is placed in parallel with transistor T7.

Current in coil L2 is energized when transistors T and T6 are ON, applying V+ voltage level to L2. Both diodes R8 and Z8 are reverse biased in this condition and block current flow. Note that both rectifier R8 and TVS (or Zener) Z8 should have a reverse standoff voltage rating of >V+. The breakdown voltage of Z8 will influence turn-off decay and can be selected accordingly.

For PWM operation, transistor T8 is PWM (ON/OFF) modulated at the desired frequency and duty cycle while T7 remains ON. When T8 is OFF and T7 is ON, current in L2 forward biases rectifier R9, producing a voltage across L2 equal in magnitude to the voltage drop across R9 and T7. The voltage drop across transistor T7 is minimal, since it is ON and allows bypass of Zener/TVS diode Z9. This is the slow-decay state, illustrated by current path 34. When both transistors T7 and T8 are OFF, current in coil L2 forward biases rectifier R9 and produces a voltage sufficient to break down Zener/TVS diode Z9, causing a voltage across L2 equal to voltage drops of R9 and Z9. This is the fast-decay state, illustrated by current path 44. Transistor T7 can be PWM controlled while T8 is off to create a variable decay rate, modulating between paths 34 and 44.

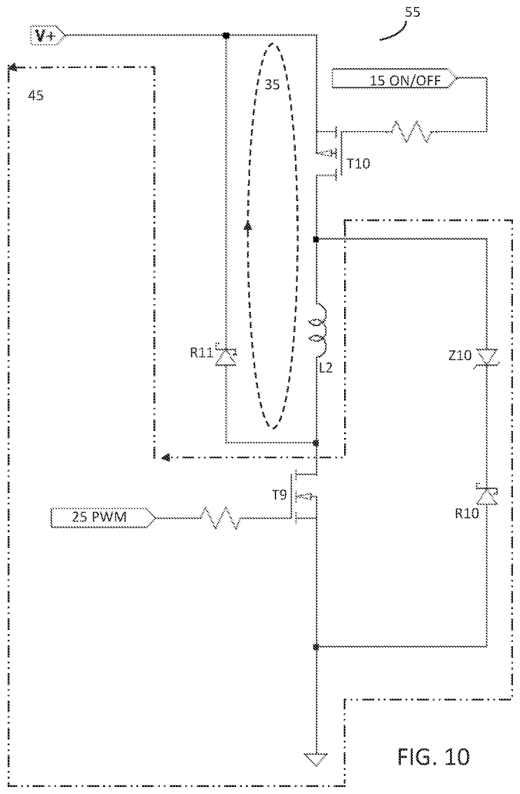

FIG. 10 is a schematic of an embodiment of a driver topology 55 that provides low-side PWM with dual recirculation paths with recirculation that utilizes a Zener or TVS diodes. This operates similarly to circuit 50, with an additional Zener/TVS diode in series with one of the rectifier diodes. High-side transistor T10 is controlled by the signal at ON/OFF pin 15. It provides a series path between V+ and ground along with inductive load L2 and low-side transistor T9. Transistor T9 is controlled by the signal at PWM pin 25. Rectifying diode R10 and Zener/TVS diode Z10 (in series) are placed in parallel with transistor T9 and load L2, while rectifying diode R11 is placed in parallel with transistor T10 and load L2, such that a series path is created between V+ and ground via rectifying diodes R10 and R11, Zener/TVS diode Z10 and load L2. Diodes R11 and R10 are forward biased, while Zener/TVS diode Z10 is reverse biased beyond the breakdown voltage when current flows from ground to V+, which provides a regeneration mode with a large voltage drop for fast decay.

Current in coil L2 is energized when T9 and T10 are ON, applying V+ voltage level to L2. Both R10 and R11 are reverse biased in this condition and block current flow. Note that both rectifiers R10 and R11 should have a reverse standoff voltage rating of >V+, but Z10 TVS (or Zener) need not. The breakdown voltage of Z10 and V+ will influence turn-off decay and can be selected accordingly.

For PWM operation, T9 is PWM modulated at the desired frequency and duty cycle while T10 remains ON. When T9 is OFF and T10 is ON, current in L2 forward biases R11, producing a voltage across L2 equal in magnitude to the voltage drop across R11 and T10. The voltage drop across T10 is minimal since it is ON. This is the slow-decay state, illustrated by path 35. When both T10 and T9 are off, current in L2 forward biases R11 and produces a voltage sufficient to forward bias R10 and break down Z10. This causes voltage equal to the sum of the voltage drops of V+, R10, R11, and Z10 across L2. This is the fast-decay state, illustrated by path 45. The breakdown voltage of Z10 can be specifically selected for a desired fast decay rate. Additionally, T9 or T10 can be PWM controlled while the other is off to create a variable decay rate, modulating between paths 35 and 45.

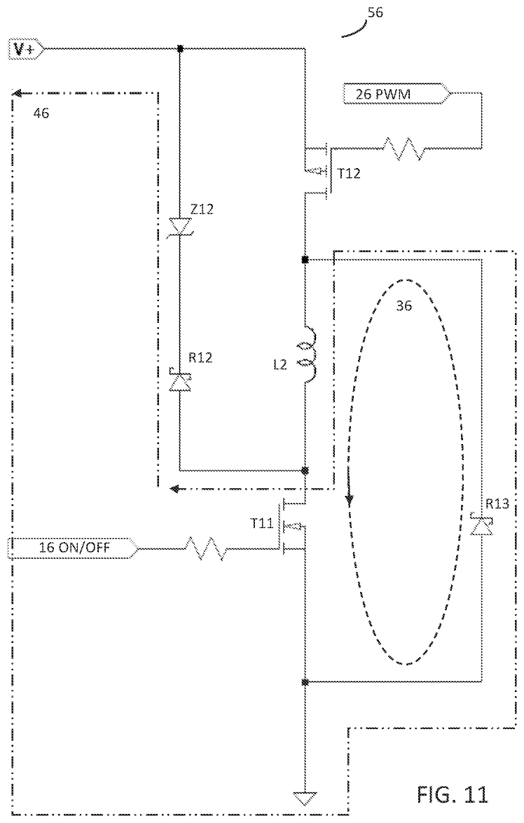

FIG. 11 is a schematic of an embodiment of a driver topology 56 that provides high-side PWM with dual recirculation paths with recirculation that utilizes a Zener or TVS diodes. This operates similarly to circuit 55, with the high and low sides swapped. Low-side transistor T11 is controlled by the signal at ON/OFF pin 16. It provides a series path between V+ and ground along with inductive load L2 and high-side transistor T12. Transistor T12 is controlled by the signal at PWM pin 26. Rectifying diode R12 and Zener/TVS diode Z12 (in series) are placed in parallel with transistor T12 and load L2, while rectifying diode R13 is placed in parallel with transistor T11 and load L2, such that a series path is created between V+ and ground via rectifying diodes R13 and R13, Zener/TVS diode Z12 and load L2. Diodes R12 and R13 are forward biased, while Zener/TVS diode Z12 is reverse biased beyond the breakdown voltage when current flows from ground to V+, which provides a regeneration mode with a large voltage drop for fast decay.

Current in coil L2 is energized when T11 and T12 are ON, applying V+ voltage level to L2. Both R12 and R13 are reverse biased in this condition and block current flow. Note that both rectifiers R12 and R13 should have a reverse standoff voltage rating of >V+, but Z12 TVS (or Zener) need not. The breakdown voltage of Z10 and V+ will influence turn-off decay and can be selected accordingly.

For PWM operation, T12 is PWM modulated at the desired frequency and duty cycle while T11 remains ON. When T12 is OFF and T11 is ON, current in L2 forward biases R13, producing a voltage across L2 equal in magnitude to the voltage drop across R13 and T11. The voltage drop across T11 is minimal since it is ON. This is the slow-decay state, illustrated by path 36. When both T11 and T12 are off, current in L2 forward biases R13 and produces a voltage sufficient to forward bias R12 and break down Z12. This causes voltage equal to the sum of the voltage drops of V+, R12, R13, and Z12 across L2. This is the fast-decay state, illustrated by path 46. The breakdown voltage of Z12 can be specifically selected for a desired fast decay rate. Additionally, T11 or T12 can be PWM controlled while the other is off to create a variable decay rate, modulating between paths 35 and 45.

Note that in FIGS. 10 and 11, the rectifier diodes (R10-13) are equivalent to those (R6-7) in FIG. 7, with the addition of Zener/TVS diode Z10/Z12 in series with one of the rectifier diodes.

Simulation results for the driver circuits show that the PWM performance in the actuated state is similar to prior art PWM-centric drivers. Meanwhile, the fast decay paths allow for substantially fast de-actuation performance, suitable for high-precision applications. Furthermore, the regenerative approach offers the benefit of using inexpensive and commonly available rectifier diodes and has better overall power efficiency. However, the inductor decay when transitioning to the OFF state will depend on the V+ level. The TVS/Zener approaches in FIGS. 8 and 9 allow the designer to implement a faster decay as compared to the regenerative approach by selecting the breakdown voltage, however the power will be dissipated in the TVS vs regenerating back to V+, such as in FIGS. 10 and 11.

It should be understood that the junction with the inductive loads L2 and L1 in the driver circuits described above can include terminals to operate an inductive load that is electrically coupled to the rest of the driver circuit while being physically separate from the rest of the driver circuit. In each of the examples disclosed, the term “driver circuit” is contemplated to refer to the rest of the circuit beside the inductive load.

While various illustrative embodiments incorporating the principles of the present teachings have been disclosed, the present teachings are not limited to the disclosed embodiments. Instead, this application is intended to cover any variations, uses, or adaptations of the present teachings and use its general principles. Further, this application is intended to cover such departures from the present disclosure that are within known or customary practice in the art to which these teachings pertain.

In the above detailed description, reference is made to the accompanying drawings, which form a part hereof. In the drawings, similar symbols typically identify similar components, unless context dictates otherwise. The illustrative embodiments described in the present disclosure are not meant to be limiting. Other embodiments may be used, and other changes may be made, without departing from the spirit or scope of the subject matter presented herein. It will be readily understood that various features of the present disclosure, as generally described herein, and illustrated in the Figures, can be arranged, substituted, combined, separated, and designed in a wide variety of different configurations, all of which are explicitly contemplated herein.

A second action can be said to be “in response to” a first action independent of whether the second action results directly or indirectly from the first action. The second action can occur at a substantially later time than the first action and still be in response to the first action. Similarly, the second action can be said to be in response to the first action even if intervening actions take place between the first action and the second action, and even if one or more of the intervening actions directly cause the second action to be performed. For example, a second action can be in response to a first action if the first action sets a flag and a third action later initiates the second action whenever the flag is set.

The present disclosure is not to be limited in terms of the particular embodiments described in this application, which are intended as illustrations of various features. Many modifications and variations can be made without departing from its spirit and scope, as will be apparent to those skilled in the art. Functionally equivalent methods and apparatuses within the scope of the disclosure, in addition to those enumerated herein, will be apparent to those skilled in the art from the foregoing descriptions. It is to be understood that this disclosure is not limited to particular methods, reagents, compounds, compositions or biological systems, which can, of course, vary. It is also to be understood that the terminology used herein is for the purpose of describing particular embodiments only and is not intended to be limiting.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein are generally intended as “open” terms (for example, the term “including” should be interpreted as “including but not limited to,” the term “having” should be interpreted as “having at least,” the term “includes” should be interpreted as “includes but is not limited to,” et cetera). While various compositions, methods, and devices are described in terms of “comprising” various components or steps (interpreted as meaning “including, but not limited to”), the compositions, methods, and devices can also “consist essentially of” or “consist of” the various components and steps, and such terminology should be interpreted as defining essentially closed-member groups.

Independent of the grammatical term usage, individuals with male, female or other gender identities are included within the term.

As used in this document, the singular forms “a,” “an,” and “the” include plural references unless the context clearly dictates otherwise. Unless defined otherwise, all technical and scientific terms used herein have the same meanings as commonly understood by one of ordinary skill in the art. Nothing in this disclosure is to be construed as an admission that the embodiments described in this disclosure are not entitled to antedate such disclosure by virtue of prior invention.

In addition, even if a specific number is explicitly recited, those skilled in the art will recognize that such recitation should be interpreted to mean at least the recited number (for example, the bare recitation of “two recitations,” without other modifiers, means at least two recitations, or two or more recitations). Furthermore, in those instances where a convention analogous to “at least one of A, B, and C, et cetera” is used, in general such a construction is intended in the sense one having skill in the art would understand the convention (for example, “a system having at least one of A, B, and C” would include but not be limited to systems that have A alone, B alone, C alone, A and B together, A and C together, B and C together, and/or A, B, and C together, et cetera). In those instances where a convention analogous to “at least one of A, B, or C, et cetera” is used, in general such a construction is intended in the sense one having skill in the art would understand the convention (for example, “a system having at least one of A, B, or C” would include but not be limited to systems that have A alone, B alone, C alone, A and B together, A and C together, B and C together, and/or A, B, and C together, et cetera). It will be further understood by those within the art that virtually any disjunctive word and/or phrase presenting two or more alternative terms, whether in the description, sample embodiments, or drawings, should be understood to contemplate the possibilities of including one of the terms, either of the terms, or both terms. For example, the phrase “A or B” will be understood to include the possibilities of “A” or “B” or “A and B.”

In addition, where features of the disclosure are described in terms of Markush groups, those skilled in the art will recognize that the disclosure is also thereby described in terms of any individual member or subgroup of members of the Markush group.

As will be understood by one skilled in the art, for any and all purposes, such as in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, et cetera. As a non-limiting example, each range discussed herein can be readily broken down into a lower third, middle third and upper third, et cetera. As will also be understood by one skilled in the art all language such as “up to,” “at least,” and the like include the number recited and refer to ranges that can be subsequently broken down into subranges as discussed above. Finally, as will be understood by one skilled in the art, a range includes each individual member. Thus, for example, a group having 1-3 components refers to groups having 1, 2, or 3 components. Similarly, a group having 1-5 components refers to groups having 1, 2, 3, 4, or 5 components, and so forth.

Various of the above-disclosed and other features and functions, or alternatives thereof, may be combined into many other different systems or applications. Various presently unforeseen or unanticipated alternatives, modifications, variations or improvements therein may be subsequently made by those skilled in the art, each of which is also intended to be encompassed by the disclosed embodiments.

### NON-LIMITING ILLUSTRATIVE EMBODIMENTS

The following is a list of non-limiting embodiments of the inventive concepts disclosed herein:

An illustrative driver circuit configured to drive an inductive load, comprising: first and second transistors configured to be operated in series with the inductive load between a voltage source and ground, wherein a first control signal to the first transistor determines an actuated state of the inductive load and a second control signal to the second transistor operates the second transistor in a pulse-width modulated state during the actuated state;
a first rectifier diode electrically coupled in parallel to the first transistor and the inductive load; and
a second rectifier diode electrically coupled in parallel to the second transistor and the inductive load,
wherein current flows along a path defined by the first rectifier diode, the first transistor and the inductive load when the second transistor in an off phase of the pulse-width modulated state and current flows along a path defined by the first rectifier diode, the second rectifier diode, and the inductive load when the first transistor transitions from an on state to an off state.

The illustrative driver circuit of claim 1 further comprising a Zener diode in series with the second rectifier diode such that current also flows through the Zener diode when the first transistor transitions from an ON state to an OFF state.

The illustrative driver circuit of any one of the preceding illustrative embodiments further comprising a transient voltage suppression (TVS) diode in series with the second rectifier diode such that current also flows through the TVS diode when the first transistor transitions from an on state to an off state.

The illustrative driver circuit of any one of the preceding illustrative embodiments, wherein the first transistor is a high-side transistor and the second transistor is a low-side transistor.

The illustrative driver circuit of any one of the preceding illustrative embodiments, wherein the first transistor is a low-side transistor and the second transistor is a high-side transistor.

The illustrative driver circuit of any one of the preceding illustrative embodiments, wherein the first and second transistors are MOSFETs.

The illustrative driver circuit of any one of the preceding illustrative embodiments, wherein the first and second transistors are BJTs.

An illustrative driver circuit configured to drive an inductive load, comprising: first and second transistors configured to be operated in series with the inductive load between a voltage source and ground, wherein a first control signal to the first transistor determines an actuated state of the inductive load and a second control signal to the second transistor operates the second transistor in a pulse-width modulated state during the actuated state;
a controlled reverse breakdown diode electrically coupled in parallel to the first transistor and the inductive load; and
a rectifier diode electrically coupled in parallel to the second transistor and the inductive load, wherein current flows along a path defined by the controlled reverse breakdown diode the first transistor and the inductive load when the second transistor in an off phase of the pulse-width modulated state and current flows along a path defined by the controlled reverse breakdown diode, the rectifier diode, and the inductive load when the first transistor transitions from an on state to an off state.

The illustrative driver circuit of any one of the preceding illustrative embodiments, wherein the controlled reverse breakdown diode is a Zener diode.

The illustrative driver circuit of any one of the preceding illustrative embodiments, wherein the controlled reverse breakdown diode is a transient voltage suppression (TVS) diode.

The illustrative driver circuit of any one of the preceding illustrative embodiments, wherein the first transistor is a high-side transistor and the second transistor is a low-side transistor.

The illustrative driver circuit of any one of the preceding illustrative embodiments, wherein the first transistor is a low-side transistor and the second transistor is a high-side transistor.

The illustrative driver circuit of any one of the preceding illustrative embodiments, wherein the first and second transistors are MOSFETs.

The illustrative driver circuit of any one of the preceding illustrative embodiments, wherein the first and second transistors are BJTs.

What is claimed:

1. A driver circuit configured to drive an inductive load, comprising:
first and second transistors configured to be operated in series with the inductive load between a voltage source and ground, wherein a first control signal to the first transistor determines an actuated state of the inductive load and a second control signal to the second transistor operates the second transistor in a pulse-width modulated state during the actuated state;
a first rectifier diode electrically coupled in parallel to the first transistor and the inductive load; and
a second rectifier diode electrically coupled in parallel to the second transistor and the inductive load,
wherein current flows along a path defined by the first rectifier diode, the first transistor and the inductive load when the second transistor in an off phase of the pulse-width modulated state and current flows along a path defined by the first rectifier diode, the second rectifier diode, and the inductive load when the first transistor transitions from an on state to an off state.

2. The driver circuit of claim 1 further comprising a Zener diode in series with the second rectifier diode such that current also flows through the Zener diode when the first transistor transitions from an ON state to an OFF state.

3. The driver circuit of claim 1 further comprising a transient voltage suppression (TVS) diode in series with the second rectifier diode such that current also flows through the TVS diode when the first transistor transitions from an on state to an off state.

4. The driver circuit of claim 1, wherein the first transistor is a high-side transistor and the second transistor is a low-side transistor.

5. The driver circuit of claim 1, wherein the first transistor is a low-side transistor and the second transistor is a high-side transistor.

6. The driver circuit of claim 1, wherein the first and second transistors are MOSFETs.

7. The driver circuit of claim 1, wherein the first and second transistors are BJTs.

8. A driver circuit configured to drive an inductive load, comprising:
first and second transistors configured to be operated in series with the inductive load between a voltage source and ground, wherein a first control signal to the first transistor determines an actuated state of the inductive load and a second control signal to the second transistor operates the second transistor in a pulse-width modulated state during the actuated state;
a controlled reverse breakdown diode electrically coupled in parallel to the first transistor and the inductive load; and
a rectifier diode electrically coupled in parallel to the second transistor and the inductive load,
wherein current flows along a path defined by the controlled reverse breakdown diode the first transistor and the inductive load when the second transistor in an off phase of the pulse-width modulated state and current flows along a path defined by the controlled reverse breakdown diode, the rectifier diode, and the inductive load when the first transistor transitions from an on state to an off state.

9. The driver circuit of claim 8, wherein the controlled reverse breakdown diode is a Zener diode.

10. The driver circuit of claim 8, wherein the controlled reverse breakdown diode is a transient voltage suppression (TVS) diode.

11. The driver circuit of claim 8, wherein the first transistor is a high-side transistor and the second transistor is a low-side transistor.

12. The driver circuit of claim 8, wherein the first transistor is a low-side transistor and the second transistor is a high-side transistor.

13. The driver circuit of claim 8, wherein the first and second transistors are MOSFETs.

14. The driver circuit of claim 8, wherein the first and second transistors are BJTs.
